(19) United States
(12) Patent Application Publication
(10) Pub. No.: US 2025/0129468 A1
(43) Pub. Date: Apr. 24, 2025

(54) SPUTTERING OF HIGH-QUALITY SUPERCONDUCTING THIN FILMS

(71) Applicant: NORTHROP GRUMMAN SYSTEMS CORPORATION, FALLS CHURCH, VA (US)

(72) Inventors: THOMAS SCOTT GESKE, Columbia, MD (US); EMAD UD DIN, Reisterstown, MD (US); HENRY KURT ERMER, Timonium, MD (US); THOMAS FRANCIS AMBROSE, Crownsville, MD (US)

(21) Appl. No.: 18/489,439

(22) Filed: Oct. 18, 2023

(51) Int. Cl. C23C 14/35; C23C 14/14; C23C 14/34; C23C 14/54; H01J 37/32; H01J 37/34

(52) U.S. Cl. CPC C23C 14/35; C23C 14/14; C23C 14/345; C23C 14/541; H01J 37/321; H01J 37/32449; H01J 37/32724; H01J 37/3464; H01J 2237/002; H01J 2237/2007; H01J 2237/332

(57) ABSTRACT

A method of forming a thin film is provided that includes providing a physical vapor deposition apparatus having a vacuum chamber. A target material is disposed on a back plate near a top portion of the vacuum chamber and a chuck to support a substrate is disposed near a bottom portion of the vacuum chamber. A working gas comprising a heavy noble gas of either krypton or xenon is injected into the vacuum chamber. Power settings are applied to the physical vapor deposition apparatus to produce an electromagnetic field to induce electric currents inside the vacuum chamber. The noble gas is ionized into an inductively coupled plasma by the electric currents. Positive ions from the inductively coupled plasma are accelerated toward the target material to displace atoms from the target material to deposit a thin film of the target material of a desired thickness on the substrate.

### GOVERNMENT INTEREST

The invention was made under U.S. Government Contract. Therefore, the U.S. Government has rights to the invention as specified in that contract.

### TECHNICAL FIELD

This disclosure relates generally to devices, systems, and method for sputtering of high-quality superconducting films.

### BACKGROUND

In a physical deposition process (PVD) ions of an inert gas (e.g., argon) are electrically accelerated toward a “target” of source material. These ions essentially eject or “sputter” the target material, atom by atom. The ejected atoms are deposited onto a substrate (e.g., wafer) to form a thin film on the substrate. One example of a target material may include niobium (Nb). During the process, however, large amounts of argon becomes incorporated into the growing thin film, which results in a high resistivity film and poor material quality.

### SUMMARY

The following presents a simplified summary to provide a basic understanding of the subject disclosure. This summary is not an extensive overview of the subject disclosure. It is not intended to identify key/critical elements or to delineate the scope of the subject disclosure. Its sole purpose is to present some concepts of the subject disclosure in a simplified form as a prelude to the more detailed description that is presented later.

One example of the subject disclosure is a method of forming a thin film that includes providing a physical vapor deposition apparatus having a vacuum chamber. A target material is disposed on a back plate near a top portion of the vacuum chamber. A chuck to support a substrate is located near a bottom portion of the vacuum chamber. The chuck has coolant flowing continuously through it during processing and is in thermal contact with the substrate to provide cooling. A working gas comprising a heavy noble gas of either krypton or xenon is injected into the vacuum chamber. Power settings are applied to the physical vapor deposition apparatus to produce an electromagnetic field to induce electric currents inside the vacuum chamber. The heavy noble gas is ionized into an inductively coupled plasma by the electric currents. Positive ions from the inductively coupled plasma are accelerated toward the target material to displace atoms from the target material to deposit a thin film of the target material of a desired thickness on the substrate. An electric field is applied to the substrate (e.g. a substrate electrical bias) to accelerate ions to the surface of the substrate.

Another example of the subject disclosure is a method of forming a superconductive thin film that includes providing a physical vapor deposition apparatus having a vacuum chamber. A target material comprising a superconductor material selected from a group consisting of niobium, indium, aluminum, titanium, molybdenum, and the like is bonded on a back plate near a top portion of the vacuum chamber. A chuck to support a substrate is located near a bottom portion of the vacuum chamber, where a temperature of the chuck is in a range from 15° C. to 150° C. A working gas comprising a heavy noble gas of either krypton or xenon is injected into the vacuum chamber. Power settings are applied to produce an electromagnetic field to induce electric currents inside the vacuum chamber. The noble gas is ionized into an inductively coupled plasma by the electric currents. Positive ions from the inductively coupled plasma are accelerated toward the target material to displace atoms from the target material to deposit a thin film of the target material on the substrate to a desired thickness.

### BRIEF DESCRIPTION OF THE DRAWINGS

The accompanying drawings, which are incorporated in and constitute a part of the specification, illustrate various systems, methods, and other examples of the disclosure. Illustrated element boundaries (e.g., boxes, groups of boxes, or other shapes) in the figures represent one example of the boundaries. In some examples one element may be designed as multiple elements or multiple elements may be designed as one element. In some examples, an element shown as an internal component of another element may be implemented as an external component and vice versa.

FIG. 1 is a schematic of an example physical vapor deposition apparatus.

FIG. 2 illustrates an example of a method for forming a superconductive thin film via a physical vapor deposition process.

FIGS. 3A and 3B are example concentration illustrations illustrating an amount of a working gas that becomes trapped in the superconductive thin film.

FIG. 4 is an example graph illustrating electrical resistivity versus film thickness.

FIG. 5 is an example graph illustrating a critical current (mA) of the superconductive thin film using both krypton and argon as the working gas.

FIG. 6 is an example graph illustrating a critical field (kA/m) of the thin film using both krypton and argon as the working gas.

FIG. 7 is an example graph illustrating a London penetration depth of the superconductive thin film using both krypton and argon as the working gas.

### DETAILED DESCRIPTION

The disclosure is now described with reference to the drawings, wherein like reference numerals are used to refer to like elements throughout. In the following description, for purposes of explanation, numerous specific details are set forth in order to provide a thorough understanding of the subject disclosure. It may be evident, however, that the subject disclosure can be practiced without these specific details. In other instances, well-known structures and devices are shown in block diagram form in order to facilitate describing the subject disclosure.

While specific characteristics are described herein (e.g., thickness, orientation, configuration, etc.), it is to be understood that the features, functions and benefits of the subject disclosure can employ characteristics that vary from those described herein. These alternatives are to be included within the scope of the disclosure and claims appended hereto.

Argon gas is typically used as a sputtering gas in a physical vapor deposition (PVD) process to create a thin film for use in superconducting applications. During the PVD process, however, argon atoms, due to their low atomic mass, can become incorporated into a thin film deposited on a substrate resulting in a high resistivity thin film and poor material quality. Specifically, during the PVD process, when the argon gas impacts a target material to displace atoms from the target material, atoms from the argon gas are reflected back (mass reflection effect) toward the thin film. These argon atoms become interstitially incorporated into the thin film. Thus, there is a large concentration of argon atoms in the resulting thin film, which as mentioned above, results in a high resistivity thin film and poor material quality. In addition, the incorporated argon atoms lead to material defects and can also act as flux pinning sites which trap flux loops in undesirable locations within circuits in the thin film. The flux trapping is a major source of repeatability and yield issues within superconducting circuits.

Still further, long process times are required for each lot (e.g., 8 wafers). The reason for the long processing time is that the process requires, 1) a high cathode power (e.g., 20 KW) applied between a target material and a chuck, 2) a high wafer bias (e.g., 300 W), and 3) a high-temperature chuck (wafer pedestal). The cathode power and the high wafer bias are major sources of creating heat within chamber. In addition, the high-temperature chuck has limited active cooling capabilities. Thus, the deposition process must be slowed in order to not to exceed a 150° C. thermal budget requirement of the wafers.

Disclosed herein is a physical vapor deposition (PVD) method of depositing a niobium (Nb) thin film onto a substrate using krypton (Kr) as the sputtering gas that overcomes the aforementioned disadvantages. When used as a sputtering gas, krypton has several beneficial properties over argon. For example, krypton has a larger atomic mass than argon and thus has a mass reflection effect that is approximately eight times less than that of argon. In other words, due to the larger atomic mass of krypton, krypton vaporizes the target material (e.g., niobium) more efficiently than argon and thus has less chance to be reflected at the surface of the sputtering target. Therefore, krypton atoms are less likely to become incorporated into the resulting thin film during the PVD process as opposed to argon atoms. In addition, krypton has a reduced kinetic reflection of atoms from the sputter target and thus a lower kinetic velocity at the wafer surface which also reduces the amount of krypton atoms incorporated into the resulting thin film. As a result, the concentration of the sputtering gas atoms (i.e., krypton atoms) in the thin film is significantly less than the concentration of argon atoms. Alternatively, xenon can be used as the working gas since xenon has similar properties and advantages as krypton.

In addition to the use of krypton, the method uses an inductive plasma coupling to provide a high degree of krypton ionization. The method also includes modifying parameters (e.g., cathode power, wafer bias, etc.) of a sputtering chamber associated with the sputtering process and providing an actively cooling, low-temperature, biasable electrostatic chuck in the sputtering chamber to ensure that the wafer remains below the 150° C. thermal budget. More specifically, the process includes applying a high voltage across two electrodes with where a wafer is disposed between the two electrodes. The high voltage ionizes the krypton gas and the positively charged ions impact the electrode containing the target material and thus vaporizes the target material. As mentioned above, the larger krypton atomic mass vaporizes the target material more efficiently than argon, which mitigates the reflection at the surface of the sputtering target. The target material vapor then diffuses through the krypton gas while a radio frequency field is applied via an inductive coil. This causes a higher degree of ionization of the plasma and reduces the kinetic energy of the target atoms as they drift towards the wafer. Finally, a second RF field is capacitively applied to the substrate through the biasable electrostatic chuck which collimates the incoming material and provides energy at the wafer surface to aid in surface diffusion of the incoming target material. This process allows controlled growth of high purity conformal thin films (e.g., niobium) with large grains.

Results from the process described above have demonstrated that the krypton deposition process provides an approximate 20% improvement in electrical resistivity and an approximate 300% improvement in residual resistivity ratio (RRR) compared to the argon deposition process. As a result, the amount of current that can be conducted through the circuits increases when using krypton as the working gas as opposed to argon. Thus, the process reduces resistivity and improves yield. The benefits of the low resistivity film can be incorporated into superconducting electronics to improve functional performance, allow scaling to smaller line sizes, and improve ground plane performances. Still further, krypton produces a higher surface roughness due to significantly larger grains produced in the thin film, which provides further evidence of improved material quality.

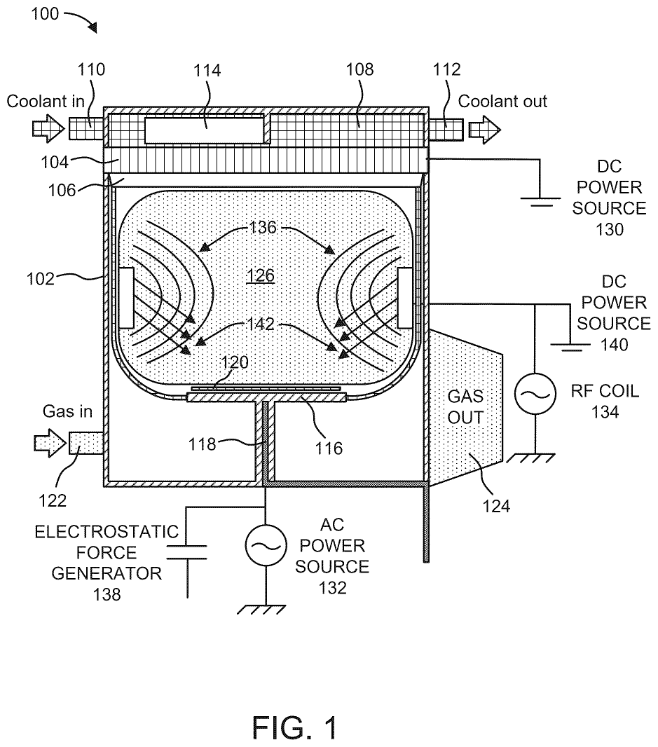

FIG. 1 is a schematic illustration of an example physical vapor deposition (PVD) apparatus 100 used for producing superconductive thin films (e.g., niobium, indium, aluminum, titanium, molybdenum, and the like) for use in superconducting applications. The PVD apparatus 100 includes a vacuum chamber 102 and a back plate 104 located on an upper portion of the vacuum chamber 102 to which a target material (e.g., niobium, indium, aluminum, titanium, molybdenum, and the like) 106 is attached. A cooling system 108 that facilitates flow of a coolant (e.g., water) is disposed above the back plate 104. The cooling system 108 includes a coolant inlet port 110 and a coolant outlet port 112 and provides cooling to the back plate 104 during the PVD process. Specifically, during the deposition process the power supplied to the PVD apparatus 100 (explained below) creates a significant amount of heat in the vacuum chamber 102. The back plate 104 serves as a heat sink to draw heat away from the target material 106 and the cooling system 108 draws the heat away from the back plate 104. A magnet 114 is also disposed above the back plate 104. The magnet 114 assists in driving a current through plasma in the vacuum chamber 102 in order to prevent shorting out the vacuum chamber 102 when a high voltage is applied.

The PVD apparatus 100 further includes a low-temperature, biasable chuck 116 located near a bottom of the vacuum chamber 102. The chuck 116 also serves as a pedestal for a substrate (e.g., wafer) 120. The pedestal is conductive and thus functions as an electrode. The thin film is formed on the substrate 120 during the deposition process. A cooling line 118 is incorporated into the chuck 116. The cooling line 118 provides a coolant (e.g., water) to the chuck 116 to maintain the chuck 116 at a low temperature in a range from approximately 15° C. to 150° C. Specifically, the cooling line 118 continuously provides the coolant to the chuck 116 such that the coolant is in thermal contact with the substrate during the PVD process so that the substrate 120 does not exceed 150° C.

The PVD apparatus 100 further includes a gas inlet port 122 and a gas outlet port 124. A working gas (e.g., krypton, xenon) 126 is introduced into the vacuum chamber 102 via the gas inlet port 122 and exits the vacuum chamber 102 via the gas outlet port 124.

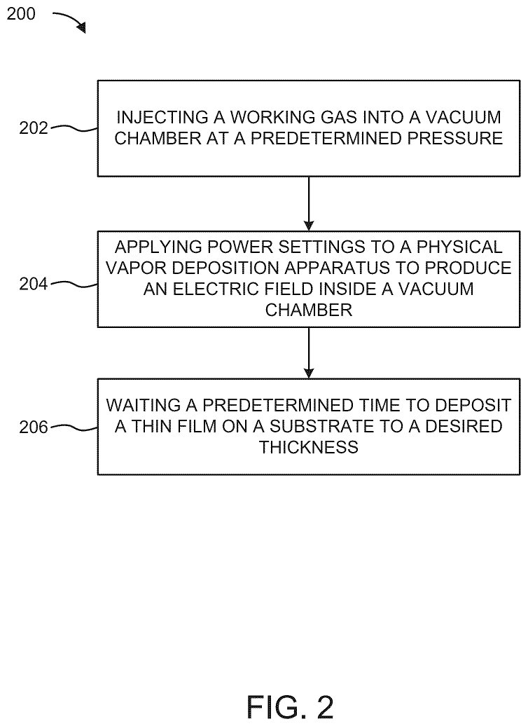

FIG. 2 is a block diagram illustrating a physical vapor deposition (PVD) method 200 where a superconductive thin film (e.g., niobium, indium, aluminum, titanium, molybdenum, and the like) is deposited on a substrate using either krypton or xenon as the working gas. Thus, referring to both FIGS. 1 and 2, at 202, the working gas (e.g., krypton, xenon) is introduced into the vacuum chamber 102 via the gas inlet port 122. The working gas is introduced through pressure in a range of approximately 0.9 mT-6.0 mT. As mentioned above, the induced electric currents excite the working gas into an inductively coupled plasma where positive ions from the inductively coupled plasma are accelerated toward the target material to displace atoms from the target material.

At 204, the following power settings are applied to the PVD apparatus 100. A first DC power source 130 supplies DC power to supply a voltage between the back plate 104 and the chuck 116 in a range of approximately 1 kW-20 kW. An AC power source 132 provides an AC bias to the substrate 120 in a range of approximately 100 W-300 W. An RF coil 134 provides power inside the vacuum chamber 102 in a range of approximately 800 W-3000 W to increase ionization of the target material 106 to thereby overcome a deposition rate of the target material 106. Specifically, the RF coil 134 provides an electromagnetic field 136 inside the vacuum chamber 102. The electromagnetic field 136 induces electric currents in the vacuum chamber 102. The electric currents in turn ionize the working gas into an inductively coupled plasma where positive ions from the inductively coupled plasma are accelerated toward the target material to displace atoms from the target material. A second RF field is capacitively applied to the substrate 120 via an electrostatic force generator 138 through the biasable electrostatic chuck 116, which collimates the incoming material and provides energy at the wafer surface to aid in surface diffusion of the incoming target material 106. A second DC power source 140 provides a DC offset power 142 inside the vacuum chamber 102 in a range of approximately 1000 W-3000 W.

At 206, after waiting a predetermined amount of time sputtered atoms from the target material 106 are deposited on the substrate 120 to form the thin film of a desired thickness. The predetermined time may vary based on the desired thickness of the thin film. The AC power source 132 that provides a bias to the substrate 120 in the presence of the plasma within the vacuum chamber 102 causes a bias to develop on the chuck (conductive pedestal) 116 so that the sputtered target material 106 ions accelerate toward the substrate 120.

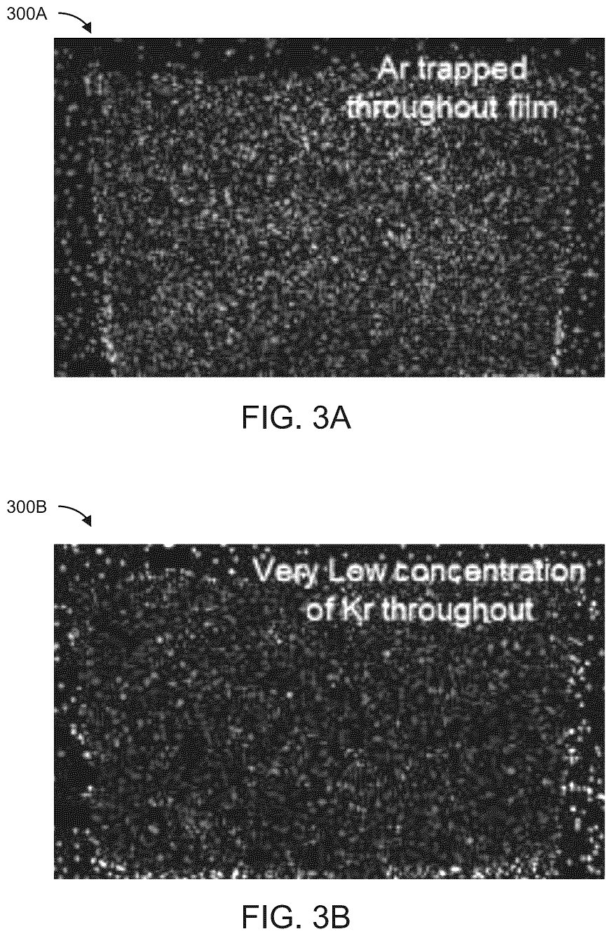

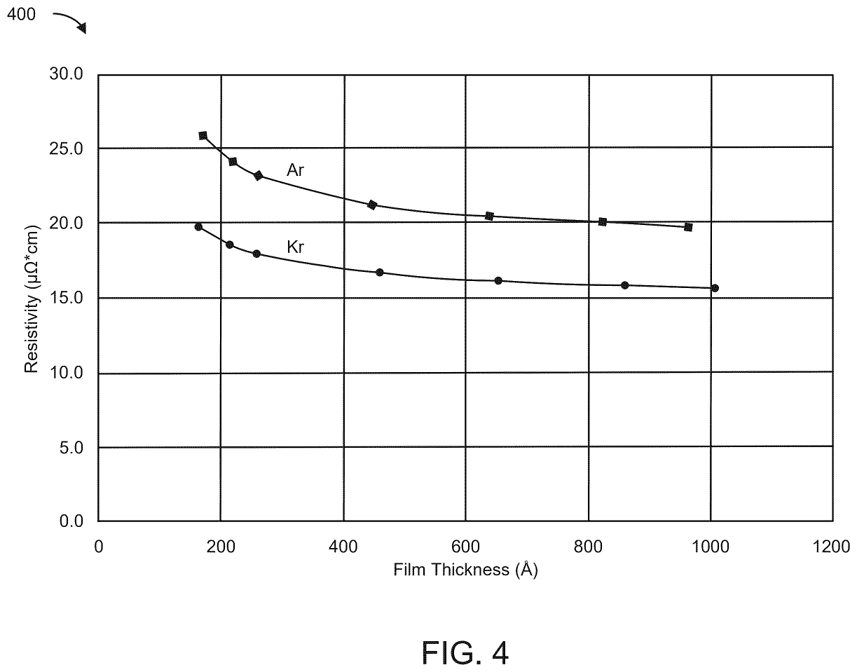

FIGS. 3A and 3B are concentration illustrations 300A, 300B of the amount of the working gas that becomes trapped in the thin film. Specifically, FIG. 3A illustrates the amount of argon trapped in the thin film and FIG. 3B illustrates the amount of krypton trapped in the thin film. As illustrated in FIGS. 3A and 3B, the amount of krypton trapped in the thin film is significantly less than the amount of trapped argon. Thus, referring to the resistivity v. film thickness graph 400 in FIG. 4, the krypton sputtered niobium thin film has an electrical resistivity that is approximately a 20% improvement in electrical resistivity and an approximate 300% improvement in residual resistivity ratio (RRR) compared to an argon deposition process. In addition, as illustrated by the graph 400, the krypton sputtered thin film can have a thickness of 1000 angstroms (Å) (100 nm) and still maintain a low electrical resistivity. Still further, a grain size of the niobium in the krypton deposition process is drastically larger than a grain size of the argon deposition process. Still further, the processing time to fabricate a lot of thin films using the krypton deposition process as compared to the argon deposition process is significantly reduced. All these improvements result in a higher quality and less defective thin film. The primary driver of these improvements is that the krypton deposition process uses a lower cathode power, a lower wafer bias power, inductive coupling of the plasma, and an actively cooling chuck. This allows the process to run continuously without risking exceeding the 150C thermal budget.

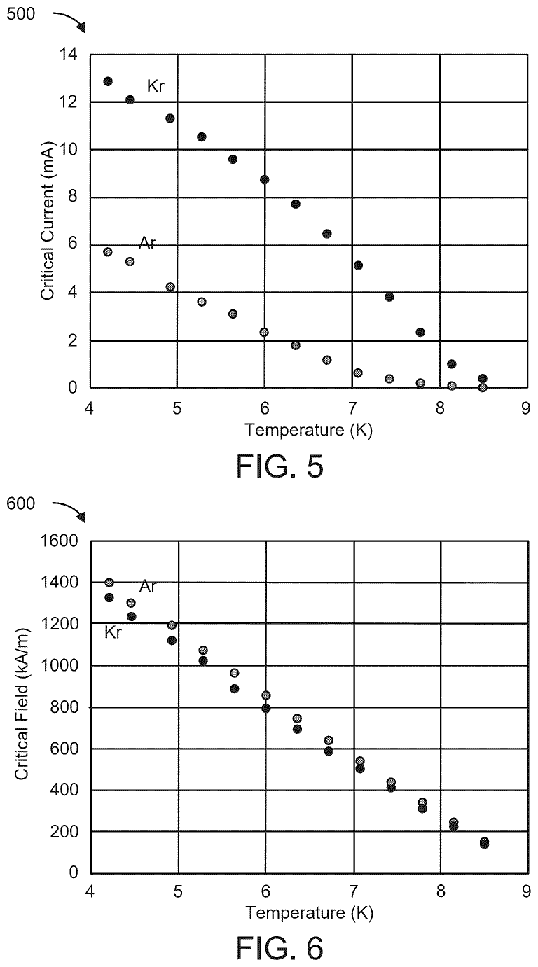

FIGS. 5-7 are graphs illustrating additional properties that improve or remain substantially the same with the use of krypton as the working gas as opposed to argon. Specifically, FIG. 5 is a graph 500 illustrating a critical current (mA) of the thin film using both krypton and argon as the working gas. The critical current is defined as the maximum current that a superconductor can conduct until the superconductor transitions from a superconducting material into a normal conducting (normal resistive state) material. As illustrated in the graph the critical current for the krypton deposition process exceeds the critical current for the argon deposition process at superconducting temperatures (K) thereby improving the critical current property.

FIG. 6 is a graph 600 illustrating a critical field (kA/m) of the thin film using both krypton and argon as the working gas. The critical field is analogous to the critical current. Specifically, the critical field is defined as the maximum magnetic field that the superconductor can be subjected to until the superconductor transitions from a superconducting material into a normal conducting (normal resistive state) material. As illustrated in the graph 600 the critical field for the krypton deposition process is substantially the same as the critical field for the argon deposition process at superconducting temperatures (K). Although there is no marked improvement in the critical field when using krypton, there is also no decrease in the critical field value when using krypton as opposed to argon.

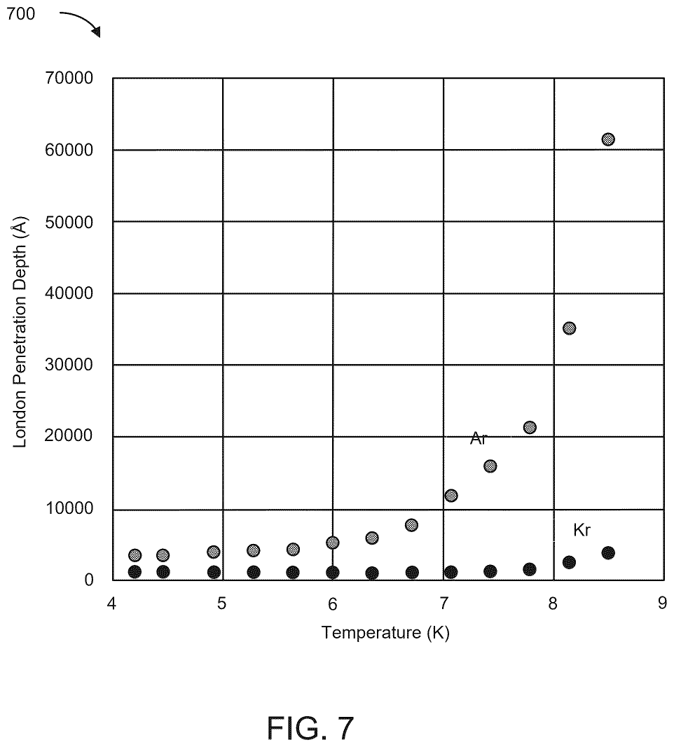

FIG. 7 is a graph 700 illustrating a London penetration depth in angstroms (Å) of the thin film using both krypton and argon as the working gas. The London penetration depth is defined as a distance (Å) that a magnetic field can penetrate into a superconducting material. As illustrated in the graph 700 the London penetration depth for the krypton deposition process has a lower value than the London penetration depth for the argon deposition process at superconducting temperatures (K), especially at superconducting temperatures ranging from 7K to 9K, thereby improving the London penetration depth property.

The descriptions above constitute examples of the disclosure. It is, of course, not possible to describe every conceivable combination of components or method for purposes of describing the disclosure, but one of ordinary skill in the art will recognize that many further combinations and permutations of the disclosure are possible. Accordingly, the disclosure is intended to embrace all such alterations, modifications, and variations that fall within the scope of this application, including the appended claims.

1. A method of forming a thin film comprising:
providing a physical vapor deposition chamber having a vacuum chamber and a target material disposed on a back plate near a top portion of the vacuum chamber and a chuck to support a substrate near a bottom portion of the vacuum chamber;
injecting a working gas comprising krypton gas into the vacuum chamber;
applying power settings to produce an electromagnetic field to induce electric currents inside the vacuum chamber, wherein the krypton gas is ionized into an inductively coupled plasma by the electric currents, and positive ions from the inductively coupled plasma are accelerated toward the target material to displace atoms from the target material; and
waiting a predetermined time to deposit a thin film of the target material on the substrate to a desired thickness.

2. The method of claim 1, wherein applying power settings to produce an electromagnetic field to induce electric currents inside the vacuum chamber includes setting an RF coil to produce power inside the vacuum chamber in a range from 800 W to 3000 W.

3. The method of claim 2, further comprising setting a first DC power source in a range from 1 kW to 20 kW to supply a voltage between the back plate and the chuck.

4. The method of claim 3, further comprising setting a second DC power source in a range from 1000 W to 3000 W to provide a DC offset power inside the vacuum chamber.

5. The method of claim 4, further comprising setting an AC power source in a range from 100 W to 300 W to bias the substrate.

6. The method of claim 5, further comprising setting a pressure in the vacuum chamber in a range of 0.9 mT to 6.0 mT.

7. The method of claim 6, further comprising providing a cooling line in the chuck and providing a coolant through the cooling line to maintain a temperature of the chuck in a range from 15° C. to 150° C.

8. The method of claim 7, wherein the temperature of the chuck is at ambient temperature.

9. The method of claim 1, wherein an electrical resistivity of the thin film is approximately 15.1 μΩ·cm.

10. The method of claim 1, wherein a thickness of the thin film is at least 50 nm.

11. The method of claim 1, wherein the target material is a superconductor material selected from a group consisting of niobium, indium, aluminum, titanium, and molybdenum.

12. A method of forming a superconductive thin film comprising:
providing a physical vapor deposition chamber having a vacuum chamber and a target material comprising a superconductor material selected from a group consisting of niobium, indium, aluminum, titanium, molybdenum, and the like disposed on a back plate near a top portion of the vacuum chamber and a chuck to support a substrate near a bottom portion of the vacuum chamber, a temperature of the chuck being in a range from 15° C. to 150° C.;
injecting a working gas comprising krypton gas into the vacuum chamber;
applying power settings to produce an electromagnetic field to induce electric currents inside the vacuum chamber, wherein the krypton gas is ionized into an inductively coupled plasma by the electric currents, and positive ions from the inductively coupled plasma are accelerated toward the target material to displace atoms from the target material; and
waiting a predetermined time to deposit a thin film of the target material on the substrate to a desired thickness.

13. The method of claim 12, wherein the temperature of the chuck is at ambient temperature.

14. The method of claim 12, wherein applying power settings to produce an electromagnetic field to induce electric currents inside the vacuum chamber includes setting an RF coil to produce power inside the vacuum chamber in a range from 800 W to 3000 W.

15. The method of claim 14, further comprising setting a first DC power source in a range from 1 kW to 20 kW to supply a voltage between the back plate and the pedestal.

16. The method of claim 15, further comprising setting a second DC power source in a range from 1000 W to 3000 W to provide a DC offset power inside the vacuum chamber.

17. The method of claim 16, further comprising setting an AC power source in a range from 100 W to 300 W to bias the substrate.

18. The method of claim 17, further comprising setting a pressure in the vacuum chamber in a range of 0.9 mT to 6.0 mT.

19. The method of claim 12, wherein a thickness of the niobium thin film is at least 50 nm.

20. The method of claim 12, wherein an electrical resistivity of the superconductive niobium thin film is approximately 15.1 μΩ·cm.
